(19) United States
(12) Patent Application Publication
(10) Pub. No.: US 2008/0113298 A1
(43) Pub. Date: May 15, 2008

(54) METHOD OF PREPARING LITHOGRAPHIC PRINTING PLATES

(76) Inventors: Harald Baumann, Osterode/Harz (DE); Ulrich Fiebag, Nienstadt (DE); Jianbing Huang, Trumbull, CT (US)

Correspondence Address: Andrew J. Anderson;Patent Legal Staff, Eastman Kodak Company, 343 State Street, Rochester, NY, 14650-2201, US

(21) Appl. No.: 11/559,932

(22) Filed: Nov. 15, 2006

(51) Int. Cl. G03F 7/004

(52) U.S. Cl. 430/302

(57) ABSTRACT

A defoamer solution is introduced into a pre-rinsing solution, developer, or post-rinsing solution in a lithographic processing apparatus in relation to the surface area of processed imageable element. Surfactants can then be used in the developer if desired, and the recirculation rates of various solutions can be reduced.

### FIELD OF THE INVENTION

This invention relates to a method of processing imaged lithographic printing plate precursors in contact with various processing solutions. A defoamer solution is introduced into at least one of the solutions to reduce a foaming problem from the presence of surfactants.

### BACKGROUND OF THE INVENTION

In lithographic printing, ink receptive regions, known as image areas, are generated on a hydrophilic surface. When the surface is moistened with water and ink is applied, the hydrophilic regions retain the water and repel the ink, and the ink receptive regions accept the ink and repel the water. The ink is transferred to the surface of a material upon which the image is to be reproduced.

Recent developments in the field of lithographic printing plate precursors concern imaging by means of lasers or laser diodes. Laser exposure does not require conventional silver halide graphic arts films as intermediate information carriers (or “masks”) since the lasers can be controlled directly by computers. High-performance lasers or laser-diodes that are used in commercially-available image-setters generally emit radiation having a wavelength of at least 700 nm, and thus the precursors are required to be sensitive in the near-infrared or infrared region of the electromagnetic spectrum. However, other radiation-sensitive compositions are designed for imaging with ultraviolet or visible radiation.

To obtain a printing plate with imagewise distribution of printable regions, it is necessary to remove regions of an imaged imageable element. The most common method for removing the undesired regions is to contact the imaged element with a developer. For negative-working printing plate precursors, exposed regions in the radiation-sensitive compositions are hardened and unexposed regions are washed off during development revealing the hydrophilic surface underneath. For positive-working printing plate precursors, the exposed regions are dissolved in a developer and the unexposed regions become an image.

The imaged elements are contacted with various solutions during processing. After imaging, the imaged element can be rinsed with a pre-rinse solution before contact with the developer, especially if the element has a water-soluble protective topcoat. After development to remove non-imaged regions, the element may be rinsed again in a post-rinse solution, and possibly treated with a specially formulated gumming or finisher solution to desensitize non-image area to assure that they will not accept ink upon printing.

Each of the processing solutions can be recirculated through the individual processing baths in the processor and they can be replenished with fresh solutions as needed. In addition, the solutions can be used as processing baths or applied as sprays.

### Problem to be Solved

Many developers used in conventional processing of lithographic printing plate precursor contain one or more surfactants or emulsifiers for various purposes. In addition, some imaged and processed elements have a protective topcoat that is water-soluble and is typically removed during processing. This topcoat often also contains one or more surfactants, so it is removed in a processing solution, the surfactants are dissolved or dispersed within that processing solution.

The presence of these surfactants, whatever their source, often create extensive foam as the processing solutions are agitated from movement of elements through the processing solutions, stirring, and recirculation means.

### SUMMARY OF THE INVENTION

To address this problem, the present invention provides a method of forming an image in a lithographic printing plate comprising:

A) imagewise exposing an imageable element comprising a support having thereon at least one imageable layer and optionally, a water-soluble topcoat,

B) optionally pre-rinsing the imagewise exposed element with a pre-rinsing solution to remove the water-soluble topcoat, if present,

C) developing the imagewise exposed element with a developer, and

D) rinsing the developed element with a post-rinsing solution to provide an imaged lithographic printing plate,

wherein a defoamer solution is introduced into at least one of the pre-rinsing solution, developer, and post-rinsing solution as needed in relation to the surface area of processed imageable element.

In some embodiments, the method further comprises either or both of the following additional steps:

E) gumming the developed and rinsed element, and

F) drying the gummed element.

More specific embodiments of the invention provide a method of forming an image in a lithographic printing plate in a processing apparatus comprising multiple processing sections, the method comprising:

A) providing an imagewise exposed imageable element comprising a support having thereon at least one imageable layer and optionally, a water-soluble topcoat,

B) introducing the imagewise exposed imageable element into a pre-rinsing section of the processing apparatus containing a pre-rinsing solution to remove the water-soluble topcoat, if present,

C) introducing the imagewise exposed imageable element into a developer section of the processing apparatus containing a developer,

D) introducing the imagewise exposed and developed imageable element into a rinsing section of the processing apparatus containing a post-rinsing solution,

E) optionally gumming the developed and rinsed element, and

F) optionally drying the gummed element,

to provide an imaged lithographic printing plate,

wherein a defoamer solution is introduced into at least one of the pre-rinsing, developer, and post-rinsing sections of the processing apparatus at a rate of from about 10 to about 100 ml/m² of processed imageable element.

We have found that the present invention can reduce the presence of foam in various processing solutions even when surfactants are purposely added to the developer or they are present as part of the dissolved layers from imaged elements. The invention thus enables a reduction in the recirculation flow rate of post-rinse solutions or their replenishers. Introducing a defoamer solution into the pre-rinse solution, developer, or post-rinse solution, or any combination thereof provides these advantages. The defoamer solution can be introduced or metered in suitable amounts or at appropriate times depending upon the need, for example, the amount or number of processed elements.

### DETAILED DESCRIPTION OF THE INVENTION

### Definitions

In addition, unless the context indicates otherwise, the various components described herein also refer to mixtures of such components. Thus, the use of the articles “a”, “an”, and “the” are not necessarily meant to refer to only a single component.

Unless otherwise indicated, percentages refer to percents by dry weight.

### Imageable Elements

The imageable elements that can be processed using the present invention can be either “positive-working” or “negative-working” imageable elements as those terms are defined above. In either case, one or more imageable layers are disposed on a suitable hydrophilic substrate. As defined in more detail below, each imageable layer comprises one or more polymeric binders (either film-forming or particulate in nature) that may also include various imaging components including initiator compositions, sensitizers, radiation absorbing compounds, surfactants, and other known components of such layers. There may be non-imageable layers such as underlayers, interlayers, and protective topcoats as well, each of which can also include one or more polymeric binders and surfactants. There is no limit to the number of layers provided that each layer contains polymers or other components that are soluble or dispersible in the developer.

The imageable elements are formed by suitable application of one or more radiation-sensitive compositions to a suitable substrate to form one or more imageable layers. This substrate can be treated or coated in various ways as described below prior to application of the radiation-sensitive composition. Some imageable elements have what is conventionally known as a water-soluble overcoat or topcoat (such as an oxygen impermeable topcoat) disposed on the imageable layer(s) as described in WO 99/06890 (Pappas et al.). Such overcoat layers can comprise one or more water-soluble polymers such as poly(vinyl alcohol), poly(vinyl pyrrolidone), and poly(vinyl imidazole) and generally are present at a dry coating weight of from about 0.1 to about 4 g/m². The overcoat layers may also include one or more surfactants.

The substrate generally has a hydrophilic surface, or at least a surface that is more hydrophilic than the applied radiation-sensitive composition on the imaging side. The substrate comprises a support that can be composed of any material that is conventionally used to prepare imageable elements such as lithographic printing plates. It is usually in the form of a sheet, film, or foil, and is strong, stable, and flexible and resistant to dimensional change under conditions of use so that color records will register a full-color image. Typically, the support can be any self-supporting material including polymeric films (such as polyester, polyethylene, polycarbonate, cellulose ester polymer, and polystyrene films), glass, ceramics, metal sheets or foils, or stiff papers (including resin-coated and metallized papers), or a lamination of any of these materials (such as a lamination of an aluminum foil onto a polyester film). Metal supports include sheets or foils of aluminum, copper, zinc, titanium, and alloys thereof.

Polymeric film supports may be modified on one or both flat surfaces with a “subbing” layer to enhance hydrophilicity, or paper supports may be similarly coated to enhance planarity. Examples of subbing layer materials include but are not limited to, alkoxysilanes, amino-propyltriethoxysilanes, glycidioxypropyl-triethoxysilanes, and epoxy functional polymers, as well as conventional hydrophilic subbing materials used in silver halide photographic films (such as gelatin and other naturally occurring and synthetic hydrophilic colloids and vinyl polymers including vinylidene chloride copolymers).

A preferred substrate is composed of an aluminum support that may be treated using techniques known in the art, including physical graining, electrochemical graining, chemical graining, and anodizing. Preferably, the aluminum sheet is electrochemically anodized using phosphoric acid or sulfuric acid and conventional procedures.

An interlayer may be formed by treatment of the aluminum support with, for example, a silicate, dextrine, calcium zirconium fluoride, hexafluorosilicic acid, a phosphate solution containing sodium fluoride, poly(vinyl phosphonic acid) (PVPA), vinyl phosphonic acid copolymer, poly(acrylic acid), or acrylic acid copolymer. Preferably, the aluminum support is mechanically grained, sulfuric acid or phosphoric acid-anodized, and treated with poly(acrylic acid) using known procedures to improve surface hydrophilicity.

The thickness of the substrate can be varied but should be sufficient to sustain the wear from printing and thin enough to wrap around a printing form. Preferred embodiments include a treated aluminum foil having a thickness of from about 100 to about 600 μm.

The backside (non-imaging side) of the substrate may be coated with antistatic agents and/or slipping layers or a matte layer to improve handling and “feel” of the imageable element.

The substrate can also be a cylindrical surface having the radiation-sensitive composition applied thereon, and thus be an integral part of the printing press. The use of such imaging cylinders is described for example in U.S. Pat. No. 5,713,287 (Gelbart).

Various imageable layer formulations are applied to the substrate in a suitable manner. There are numerous publications describing such formulations for both negative-working and positive-working elements (or lithographic printing plate precursors) that can be processed using the present invention.

For example, imageable layer formulations for negative-working imageable elements generally include a radically polymerizable component, a radical initiator, a radiation absorbing compounds (sometimes known as a sensitizer), and one or more polymeric binders. Representative negative-working compositions and imageable elements are described for example, in U.S. Pat. No. 6,309,792 (Hauck et al.), U.S. Pat. No. 6,569,603 (Furukawa), U.S. Pat. No. 6,582,882 (Pappas et al.), U.S. Pat. No. 6,787,281 (Tao et al.), U.S. Pat. No. 6,893,797 (Munnelly et al.), and U.S. Pat. No. 7,097,956 (Miyamoto et al.), U.S. Published Patent Application 2003/0118939 (West et al.), and EP Patent Publications 1,079,276A1 (Lifka et al.), 1,182,033A1 (Fujimaki et al.), 1,449,650A1 (Goto), all of which are incorporated herein by reference.

Positive-working imageable elements may include one or more imageable layers on the substrate, each layer comprising one or more polymeric binders that are solubilized in alkaline developers upon exposure and a radiation absorbing compound. Useful polymeric binders having these properties are well known and representative positive-working compositions and elements are described for example in U.S. Pat. No. 6,294,311 (Shimazu et al.), U.S. Pat. No. 6,352,812 (Shimazu et al.), U.S. Pat. No. 6,593,055 (Shimazu et al.), U.S. Pat. No. 6,352,811 (Patel et al.), U.S. Pat. No. 6,358,669 (Savariar-Hauck et al.), U.S. Pat. No. 6,528,228 (Savariar-Hauck et al.), U.S. Pat. No. 6,541,181 (Levanon et al.), and U.S. Pat. No. 7,097,956 (noted above), U.S. Patent Application Publications 2003/0129526 (Haley et al.) and 2004/0067432 A1 (Kitson et al.), and WO 2003/076113 (Knoedler et al.) and WO 2001/09682 (Levanon et al.), all of which are incorporated herein by reference.

Some imageable elements comprise a topcoat or oxygen impermeable protective layer that is composed of one or more film-forming polymeric binders such as a poly(vinyl alcohol), poly(vinyl pyrrolidone), or mixtures thereof. Such topcoats also often include one or more surfactants. During processing, the topcoat is dissolved in one or more processing solutions and the dissolved or dispersed components such as the surfactants can generate unwanted foam.

The imageable elements have any useful form including but not limited to, printing plate precursors, printing cylinders, printing sleeves and printing tapes (including flexible printing webs). Preferably, the imageable members are printing plate precursors that can be of any useful size and shape (for example, square or rectangular) having the requisite imageable layer disposed on a suitable substrate. Printing cylinders and sleeves are known as rotary printing members having the substrate and imageable layer in a cylindrical form. Hollow or solid metal cores can be used as substrates for printing sleeves.

### Imaging Conditions

During use, the imageable element is exposed to a suitable laser providing “violet”, near-infrared, or infrared radiation, depending upon the element sensitivity, at a wavelength of from about 250 to about 1500 nm. Preferably, imaging is carried out using an infrared laser providing imaging radiation at a λₘₐₓ of about 405 nm (“violet” irradiation) or from about 810 to about 830 nm (IR irradiation). The laser used to expose the imageable element is preferably a diode laser, because of the reliability and low maintenance of diode laser systems, but other lasers such as gas or solid-state lasers may also be used. The combination of power, intensity and exposure time for laser imaging would be readily apparent to one skilled in the art. Presently, high performance lasers or laser diodes used in commercially available imagesetters emit infrared radiation at a wavelength of from about 800 to about 850 nm or from about 1060 to about 1120 nm.

The imaging apparatus can function solely as a platesetter or it can be incorporated directly into a lithographic printing press. In the latter case, printing may commence immediately after imaging and development, thereby reducing press set-up time considerably. The imaging apparatus can be configured as a flatbed recorder or as a drum recorder, with the imageable member mounted to the interior or exterior cylindrical surface of the drum. An example of an useful imaging apparatus is available as models of Creo Trendsetter® imagesetters available from Eastman Kodak Company (Burnaby, British Columbia, Canada) that contain laser diodes that emit near infrared radiation at a wavelength of about 830 nm. Other suitable imaging sources include the Crescent 42T Platesetter that operates at a wavelength of 1064 nm (available from Gerber Scientific, Chicago, Ill.) and the Screen PlateRite 4300 series or 8600 series platesetter (available from Screen, Chicago, Ill.). Additional useful sources of radiation include direct imaging presses that can be used to image an element while it is attached to the printing plate cylinder. An example of a suitable direct imaging printing press includes the Heidelberg SM74-DI press (available from Heidelberg, Dayton, Ohio).

Generally, infrared imaging can be carried out generally at an imaging (exposure) energy of at least 20 mJ/cm² and up to and including 500 mJ/cm², preferably at from about 50 to about 300 mJ/cm².

Imaging radiation in the ultraviolet to visible region of the spectrum, and particularly at a wavelength of at least 250 nm and up to and including 600 nm, can be carried out generally using energies of at least 0.01 mJ/cm² and up to and including 0.5 mJ/cm², and preferably at least 0.02 and up to and including about 0.1 mJ/cm². The preferred lasers are violet laser diodes emitting at about 405 nm and frequency double Nd-YAG lasers operating at 532 nm. Examples of platesetters for imaging in this spectral region are Fuji's Luxel Vx-9600 Platesetter, Prosetter platesetters from Heidelberger Druckmaschinen, and Mako platesetters from ECRM.

### Processing Method

Imaged elements are generally processed in various processing solutions including a developer in order to provide the lithographic surface needed for lithographic printing. Automatic developing apparatus or machines are widely used for lithographic printing plate production and printing operations. Thus, the method of the present invention is generally carried out using such a processing apparatus that has various sections, baths, or compartments containing the desired processing solutions including a developer. The processing apparatus can include a pre-rinse section, developer section, post-rinse section, and optionally other sections for gumming or drying the processed element. The apparatus also generally includes means for transporting the element through the machine, vessels or containers for processing solutions that are metered into the processing sections, recirculation means (such as pumps), electronic controlling devices, spraying means (such as nozzles), brushes, applicators, sponges, rollers, filters, and the various hoses and other parts needed for plumbing and movement of the processing solutions.

Generally, the processed elements are immersed within each processing solution and transported from section to section with submerged guide rollers. However, spray nozzles can be used in any of the sections to contact the processed element with a processing solution.

Each processing solution can be automatically replenished as needed, or in the case of the developer, it can be either replenished, regenerated, or both, as needed, for example based on processed surface area of processed imaged elements or time of use.

The imagewise exposed element is contacted with at least a developer solution in a developer section and a post-rinse solution in a post-rinse section of the processing apparatus. Preferably, development is preceded with contact with a pre-rinse solution in a pre-rinse section of the processing apparatus. The defoamer solution (described below) can be introduced, or metered, into any one or more of these sections as needed and in relation to the surface area (generally, m²) of the processed elements, and preferably, it is introduced into the post-rinse section.

Additional sections can be used for gumming the processed element using a conventional gumming solution, as well as a drying section.

A preheat station can be used prior to the pre-rinse section whereby the imagewise exposed element is heated using circulated heated air or an infrared heater.

Examples of commercial processing apparatus that can be used to carry out the present invention include but are not limited to the Mercury 850 Processor, Mercury News Processor, and Violet Compact Processor (all from Eastman Kodak Company), Raptor 68 Polymer HW processor (Gluns & Jensen, Denmark), PK-910 Processor (Eastman Kodak Company), Inca 70 Processor (Heights, UK), and ILP 68 Photo Polymer Processor (Colenta, Austria).

More specifically, the method of this invention can be carried out using a processing apparatus having the components and processing conditions described below. Processing can be carried out generally at a speed of from about 0.3 to about 3 meters/minute, and preferably at from about 0.6 to about 2 meters/minute.

After imaging, imagewise exposed element can be heated at from about 80 to about 200° C. (preferably from about 85 to about 135° C.) for from about 1 to about 100 seconds (preferably from about 5 to about 60 seconds) in a pre-heat section.

After this pre-heating, the element can be washed, for example, using a spray tube with multiple spray nozzles, with a pre-rinse solution in a pre-rinse section at from about 10 to about 40° C. for at least 1 and up to 10 seconds (preferably from about 2 to about 5 seconds). The pre-rinse solution is generally an aqueous solution, such as tap water or deionized water. A heater (such as an IR heater) can also be used in the pre-rinse section. The pre-rinse solution can be replenished as needed, for example with fresh tap water at from about 50 to about 2000 ml/m² of processed element (preferably from about 100 to about 500 ml/m²).

The washed element is then developed in a developer section of the processor apparatus at from about 15 to about 40° C. (preferably from about 20 to about 30° C.) using any suitable developer, examples of which are described below. The developer section usually has a pair of entrance rollers (optionally scrub brush rollers), and optionally a spray tube with a series of nozzles, and a pair of squeeze rollers as the element exits the section. A heater can also be used in the developer section. The element is usually kept in the developer section for from about 5 to about 40 seconds and preferably for from about 10 to about 30 seconds. The developer can be replenished using the same developer or a specially designed replenisher at a rate of from about 5 to about 300 ml/m² of processed element (preferably from about 20 to about 200 ml/m²).

The developer composition commonly includes one or more of surfactants, chelating agents (such as salts of ethylenediaminetetraactic acid), organic solvents, and alkaline components (such as inorganic metasilicates, organic metasilicates, alkali hydroxides, phosphates, and bicarbonates). It is particularly likely that the developer contains one or more surfactants that may cause foaming in the developer or post-rinsing sections of the processing apparatus.

Alkaline aqueous developers generally have a pH of from about 7 to about 14 and preferably from about 8 to about 13. Useful commercial alkaline aqueous developers include 3000 Developer, 9000 Developer, Goldstar Developer, Greenstar Developer, ThermalPro Developer, Protherm Developer, MX1813 Developer, MX1710 Developer, and Violet 500 Developer (all available from Eastman Kodak Company).

Developers can also be organic solvent-containing developers that are generally single-phase solutions including one or more organic solvents in an amount of from about 0.5 to about 15 weight % (based on total developer weight). Particularly useful organic solvents include but are not limited to, benzyl alcohol, reaction products of phenol with ethylene oxide (phenol ethoxylates) or propylene oxide (phenol propoxylates), such as ethylene glycol phenyl ether (2-phenoxyethanol), (b) esters and ethers of alkylene glycols having 6 or less carbon atoms such as ethylene glycol, propylene glycol, diethylene glycol, 2-ethoxyethanol, 2(-2-ethoxy)ethoxyethanol, and 2-butoxyethanol. Preferably, benzyl alcohol, 2-phenoxyethanol, or both, are present in an amount of from about 2 to about 10 weight % (based on total developer weight) as the only organic solvent. Such developers generally have a lower pH of 11 or less and at least 6, and preferably from about 6.5 to about 11. Representative solvent-containing developers include but are not limited to ND-1 Developer, Developer 980, “2 in 1” Developer, ProNeg D-501 Developer, SP-200 Developer, 955 Developer, 956 Developer, and 980 Developer (all available from Eastman Kodak Company).

After development, the imaged and developed element is contacted with a post-rinse solution in a post-rinse section of the processing apparatus for from about 1 to about 20 seconds (preferably from about 2 to about 10 seconds). The post-rinse section can also include a spray tube with spray nozzles to introduce the post-rinse solution, and optionally brush rollers, squeeze rollers, and a heater. The post-rinse solution is sometimes known in the art as a “rinsing bath” and is generally kept at a temperature of from about 5 to about 40° C. and preferably at from about 10 to about 30° C. The post-rinse solution is generally an aqueous solution such as tap water or deionized water. The post-rinse solution can also be replenished using fresh water at from about 50 to about 2000 ml/m² of processed element (preferably from about 100 to about 500 ml/m²). Surfactants may be carried into the post-rinsing solution from the developer, causing foaming to occur.

Optionally, a gumming section or station can be used after the post-rinse section to apply a conventional gum, usually by application rollers. Gumming is generally carried out for from about 1 to about 20 seconds (preferably from about 2 to about 10 seconds) at room temperature. Gumming solutions generally include polymers such as poly(vinyl alcohol), poly(methacrylic acid), poly(methacrylamide), poly(hydroxyethyl methacrylate), or poly(vinyl methylether) or a gelatin, a polysaccharide, a cellulose, alginic acid, or preferably gum arabic.

Normally, the processed element is dried after gumming or post-rinsing for from about 2 to about 20 seconds at from about 20 to about 80° C. using conventional drying means (for example, warm air).

In addition, a postbake operation can be carried out, with or without a blanket exposure to UV or visible radiation. Alternatively, a post-UV floodwise exposure (without heat) can be used to enhance the performance of the imaged element. Blanket (floodwise or overall) UV exposure can be carried out using a suitable source of UV radiation such as a Spectramatch™ L1250 diazo/photopolymer lamp such as that available from OLEC Corporation (Irvine, Calif.).

The defoamer solution is introduced or metered into at least one of the pre-rinsing solution, developer, and post-rinsing solution at a rate of from about 1 to about 500 ml/m² (preferably from about 10 to about 100 ml/m²) of processed imageable element. The defoamer solution can be introduced into one or more of the solutions in relation to the rate of addition or recirculation of pre-rinsing, developer, or post-rinsing solution. Preferably, the defoamer solution is metered into the post-rinse solution as needed, for example based on the surface area of processed element.

The defoamer solution can be supplied and used at the desired concentration, or it can be formed by diluting a concentrated defoamer solution, or dissolving a solid defoamer, prior to or simultaneously with metering it into least one of the noted solutions. Generally, the processor section into which the defoamer solution is introduced has an appropriate introduction means such as a metering apparatus (for example, a pump) and a device to control the metering rate. Thus, the introducing means can be a pump designed to meter the defoamer solution in response to a controller means. The defoamer can be metered into a processor section using the same means that triggers developer or post-rinsing solution replenishment. Optionally, it can be metered together with an antioxidant solution when element processing is stopped. The amount of metered defoamer solution can be estimated based on the amount and type of developer (for example, the concentration of surfactant) and the replenishment rate of the developer or post-rinsing solution. The defoamer solution can be diluted with water as needed.

Useful defoamer solutions can be obtained from a number of commercial sources including but not limited to Degussa-Huels AG (Germany), BYK Chemie (Wallington, Conn.), and Tschimmer & Schwartz (Germany). There are various classes of defoamer solutions that include various components designed to reduce foam. Such defoamer solutions can comprises a fat defoamer, alkylene oxide adduct, metal soap, silicone or silicone-containing compound, wax defoaming agent, dispersion defoaming agent, or sulfo-carboxylic ester defoaming agent. Particular commercial defoamer solutions that can be used in this invention are described in the Examples below. The defoamer is generally used at a concentration of from about 0.01 to about 50% in an aqueous solution, and most preferably at a concentration of from about 0.1 to about 10% aqueous solution.

### Printing

Printing with the processed imageable element can be carried out by applying a lithographic ink and fountain solution to the printing surface of the imaged and developed element. The fountain solution is taken up by the surface of the hydrophilic substrate revealed by development, and the ink is taken up by the remaining hydrophobic regions of the imaged layer. The ink is then transferred to a suitable receiving material (such as cloth, paper, metal, glass, or plastic) to provide a desired impression of the image thereon. If desired, an intermediate “blanket” roller can be used to transfer the ink from the imaged member to the receiving material. The imaged members can be cleaned between impressions, if desired, using conventional cleaning means.

The following examples are provided to illustrate the practice of this invention but they are not meant to be limiting in any manner.

### EXAMPLES

The following materials were used in the Examples:

Amphotensid B5 is a fatty acid amide alkyl betaine that was obtained from Zschimmer & Schwarz (Germany).

Amphotensid D1 (40%) is an N-alkylamine acid, triethanol ammonium salt that was obtained from Zschimmer & Schwarz.

Amphotensid CT (100%) is a coco acid amido alkyl glucinate that was obtained from Zschimmer & Schwarz.

Byk® 021 is a polysiloxane base defoamer that was obtained from BYK Chemie (Wallingford, Conn.).

DOWANOL DPM is dipropylene glycol methyl ether.

Electra Excel HRO® Positive lithographic plate for 810-830 nm laser exposure is available from Kodak Polychrome Graphics GmbH (Osterode, Germany).

Foam Ban HV 820G is a defoamer for aqueous metal work fluids that was obtained from Münzing (Germany).

HYDROPALAT 3204 is a hydrolysis stable complexing agent that was obtained from Cognis (Germany).

Marlon ARL is a sodium salt of a C₁₀ to C₁₃-alkylbenzene sulfonic acid that was obtained from Degussa-Huels AG (Germany).

Silfoam SRE is a silicon defoamer that was obtained from Wacker (Germany).

Synoperonic T304 is an adduct of polyoxyethylene and polyoxypropylene on ethylene diamine that was obtained from ICI Surfactants (various countries).

TEXAPON 842 is a sodium octyl sulfate that was obtained from Cognis (Germany).

Thermal News Gold® Negative working lithographic plate based on photopolymerization for 810-830 nm laser exposure is available from Kodak Polychrome Graphics GmbH (Osterode, Germany, a subsidiary of Eastman Kodak Company).

TRILON B is tetrasodium-EDTA that was obtained from BASF (Germany).

TRILON BS is ETDA that was obtained from BASF.

Triton® H66 is an aryl-EO-phosphate, potassium salt that was obtained from Union Carbide.

Violet Print® Negative working lithographic plate based on photopolymerization for 405 nm laser exposure is available from Kodak Polychrome Graphics GmbH.

850 S is an acidic finishing gum that is available from Kodak Polychrome Graphics GmbH.

900 K is a silicon defoamer emulsion that is available from Kodak Polychrome Graphics GmbH.

The Raptor 68 Polymer HW processor from Glunz & Jensen provides for processing lithographic printing plate precursors to provide printing plates using the following steps:

Preheat

Development supported by two scrub brushes,

Post-rinse section with one brush and having water circulation system, and

Gumming section.

The following TABLE I shows the defoamers and the dilution ratios that were used in the Examples.

TABLE I

| Defoamer | Commercial name | Dilution |
|---|---|---|
| DF1 | Silfoam SRE | 1 part defoamer + 100 parts of water |
| DF2 | Byk ® 021 | 1 part defoamer + 100 parts of water |
| DF3 | Foam Ban HV 820G | 1 part defoamer + 100 parts of water |
| DF4 | 900 K | 1 part defoamer + 100 parts of water |

### Examples 1 to 3 and Comparative Examples 1 to 4

In these examples, the defoamer was metered to the developing section of the processor during processing imageable elements that are sensitized for imaging at 405 nm.

The Raptor 68 Polymer HW processor was filled with developer D1 (TABLE II). The following settings were used:

Transport speed of 100 cm/min,

Preheat 105° C. measured with a Thermax control strip on the plate back side,

Prewash unit used with water-circulation (removal of oxygen protective overcoat),

Developer replenishment rate of 80 ml/m² of regenerator D1 (R) (TABLE II),

Antioxidant rate of 40 ml/h of D1 (R),

Developer temperature of 23° C.,

Replenishment rate of water into the post rinse section of 200 ml/m², circulation mode used,

Setting of the defoamer solution metering into the developing section (see TABLE III), and

Gum section was filled with gum 850 S.

The developer composition is described below in TABLE II. The Defoamer solution was added to the developing section using a bellow pumps. The type of defoamer and the rate of addition are summarized below in TABLE III.

TABLE II

| | D1 | D1(R) |
|---|---|---|
| Amphotensid B5 (40%) | 5.00% | 5.00% |
| Potassium hydroxide | 0.20% | 1.40% |
| Water | 94.80% | 93.60% |

To test the efficiency of defoaming, 100 Violet Print® Negative working lithographic printing plates having a size of 540×670 mm² were developed without discontinuation for each Example and Comparative Example and the amount of foam in the post rinse bath or in other parts of the processor was evaluated. The effects of defoamer that was metered into the developing section (water circulation mode of the post rinse section) are shown in TABLE III.

TABLE III

| | | Defoamer | | |
|---|---|---|---|---|
| | Developer | solution | Defoamer addition | Observation |
| Example 1 | D1 | DF1 | A mixture of 2 liters of DF1 and | The plates developed cleanly. A very small amount of |
| | | | 20 liters of D1 was put into the | foam was seen in the developing section and a very |
| | | | processor and the automatic DF1 | small amount of foam was seen on the post rinse bath |
| | | | metering was set to 15 ml/m² and | water surface. After processing of 100 plates and 5 days |
| | | | 7.5 ml/h | since filling the developer into the processor, no |
| | | | | foaming was observed in the developing and post rinse |
| | | | | sections. |
| Example 2 | D1 | DF2 | A mixture of 2 liters of DF1 and | The plates developed cleanly. A very small amount of |
| | | | 20 liters of D1 was put into the | foam was seen in the developing section and a very |
| | | | processor and the automatic DF2 | small amount of foam was seen on post rinse bath water |
| | | | metering was set to 15 ml/m² and | surface. After processing of 100 plates and 5 days since |
| | | | 7.5 ml/h | filling the developer into the processor, no foaming was |
| | | | | observed in the developing and post rinse sections. |
| Example 3 | D1 | DF3 | A mixture of 2 liters of DF1 and | The plates developed cleanly. A very small amount of |
| | | | 20 liters of D1 was put into the | foam was seen in the developing section and a very |
| | | | processor and the automatic DF3 | small amount of foam was seen on post rinse bath water |
| | | | metering was set to 15 ml/m² and | surface. After processing of 100 plates and 5 days since |
| | | | 7.5 ml/h | filling the developer into the processor, no foaming was |
| | | | | observed in the developing and post rinse sections. |
| Comparative | D1 | None | 0 | The plates developed cleanly, and foaming was seen in |
| Example 1 | | | | the developing section especially during filling the |
| | | | | processor and during cleaning of the developing section |
| | | | | with water. After loading of 100 plates, foaming was |
| | | | | seen in the post rinse section resulting in foam exiting |
| | | | | the machine. |
| Comparative | D1 | DF1 | A mixture of 2 liters of DF1 and | The plates developed cleanly. When the |
| Example 2 | | | 20 liters of D1 was put into the | developer/defoamer mixture was directed into the |
| | | | processor and the automatic DF1 | processor, no foam was seen during processing of the |
| | | | metering was set to 0 ml/m² and 0 ml/h | plates. After using the developer/defoamer mixture for |
| | | | | 5 days after preparation, high foam was seen in the post |
| | | | | rinse section, resulting in foam exiting the machine. |
| Comparative | D1 | DF2 | A mixture of 2 liters of DF2 and | The plates developed cleanly. When the |
| Example 3 | | | 20 liters of D1 was put into the | developer/defoamer mixture was directed into the |
| | | | processor and the automatic DF2 | processor, no foam was seen during processing of the |
| | | | metering was set to 0 ml/m² and 0 ml/h | plates. After using the developer/defoamer mixture for |
| | | | | 5 days, high foam was seen in the post rinse section, |
| | | | | resulting in foam exiting the machine. |
| Comparative | D1 | DF3 | A mixture of 2 liters of DF3 and | The plates developed cleanly. When the |
| Example 4 | | | 20 liters of D1 was filled in the | developer/defoamer mixture was directed after |
| | | | processor and the automatic DF3 | preparation into the processor, no foam was seen during |
| | | | metering was set to 0 ml/m² and 0 ml/h | processing of the plates. |
| | | | | After using the developer/defoamer mixture for 5 days |
| | | | | after preparation, high foam was seen in the post rinse |
| | | | | section, resulting in foam exiting the machine. |

### Examples 4 and 5 & Comparative Examples 5 to 7

In these examples, positive-working printing plates were prepared using a processing method in which the defoamer was metered to the developing section.

A Mercury 850 processor that is available from Kodak Polychrome Graphics GmbH was filled with the corresponding developer (see TABLE IV below). The following settings have been used:

Transport speed 100 cm/min,

Developer top up rate of 150 ml/m²,

Developer temperature of 23° C.,

Setting of the defoamer solution for the developing section (see TABLE V below), and

Gum section was filled with gum 850 S.

TABLE IV

| | |
|---|---|
| Water | 85.10% |
| Sodium meta silicate 5-hydrate | 12.00% |
| Triton ® H66 | 2.50% |
| Synperonic T 304 | 0.20% |
| Marlon ARL | 0.20% |

To test the efficiency of defoaming in the developing section, 100 Electra Excel HRO® plates having a size 540×670 mm² were developed within in a working day using 3 hours for each example. The results are summarized below in TABLE V.

TABLE V

| | | Defoamer | | |
|---|---|---|---|---|
| | Developer | Solution | Defoamer Addition | Observations |
| Example 4 | D2 | DF1 | A mixture of 2 liters of DF1 and 20 | The plates developed cleanly. A very small |
| | | | liters of D2 was put into the | amount of foam was seen on the post rinse bath |
| | | | processor and the automatic DF1 | water surface. After processing 100 plates and 5 |
| | | | metering was set to 15 ml/m² and | days since filling the developer, no foaming was |
| | | | 7.5 ml/h | observed in the developing and post rinse sections. |
| Example 5 | D2 | DF4 | A mixture of 2 liters of DF4 and 20 | The plates developed cleanly. A very small |
| | | | liters of D2 was put into the | amount of foam was seen on the post rinse bath |
| | | | processor and the automatic DF4 | water surface. After processing 100 plates and 5 |
| | | | metering was set to 15 ml/m² and | days since filling the developer into the processor, |
| | | | 7.5 ml/h | no foaming was observed in the developing and |
| | | | | post rinse sections. |
| Comparative | D2 | DF1 | A mixture of 2 liters of DF1 and 20 | The plates developed cleanly. When the |
| Example 5 | | | liters of D2 was put into the | developer/defoamer mixture was directed into the |
| | | | processor and the automatic DF1 | processor after preparation, no foaming was seen |
| | | | metering was set to 0 ml/m² and 0 ml/h | during processing of the plates. After using the |
| | | | | developer/defoamer mixture for 5 days after |
| | | | | preparation, high foam formation was observed |
| | | | | resulting in foam exiting the machine. |
| Comparative | D2 | DF4 | A mixture of 2 liters of DF4 and 20 | The plates developed cleanly. When the |
| Example 6 | | | liters of Ds was put into the | developer/defoamer mixture was directed into the |
| | | | processor and the automatic DF4 | processor after preparation, no foam was seen |
| | | | metering was set to 0 ml/m² and 0 ml/h | during processing of the plates. After using the |
| | | | | developer/defoamer mixture for 5 days, high foam |
| | | | | formation was observed resulting in foam exiting |
| | | | | the machine. |
| Comparative | D2 | None | 0 | The plates developed cleanly but high foam |
| Example 7 | | | | formation was seen resulting in foam exiting the |
| | | | | machine. |

### Examples 6 and 7 and Comparative Example 8

In these examples, the defoamer was metered into the post rinse section during the processing of photosensitive element that was sensitized to 810 to 830 nm.

The Raptor 68 Polymer HW processor was filled with developer D3 (See TABLE VI below). The following settings were used:

Transport speed of 100 cm/min,

Preheat to 105° C., measured with a Thermax control strip on the plate back side,

Prewash unit used with water-circulation (removal of oxygen protective overcoat),

Developer D3 top up rate of 80 ml/m²,

Developer temperature of 23° C.,

Replenishment rate of water into the post rinse section of 200 ml/m², circulation mode used,

Metering settings for the defoamer solution to the post rinse section are shown in TABLE III above, and

Gum section was filled with gum 850 S.

The developer compositions are described below in TABLE VI.

The Defoamer solution was added to the developing section using a bellow pumps. The types of defoamer and the rates of addition are summarized below in TABLE VII.

To test the efficiency of defoaming in the post rinse section, 100 Thermal News Gold® Printing Plates having a size 540×670 mm² were developed without discontinuation for each example and the amount of foam in the developing section or in other parts of the processor was observed.

TABLE VI

| | |
|---|---|
| Deionized water | 74.220% |
| 900 K | 0.019% |
| TEXAPON 842 | 6.991% |
| Amphotensid D 1(40%) | 8.084% |
| Diethanol amine | 1.500% |
| p-Toluene sulfonic acid | 0.156% |
| DOWANOL ® DPM | 3.584% |
| Amphotensid CT(100%) | 3.234% |
| HYDROPALAT 3204 | 1.081% |
| TRILON B | 1.081% |
| TRILON BS | 0.049% |

TABLE VII

| | Developer | Defoamer Solution | Defoamer Addition | Observation |
|---|---|---|---|---|
| Example 6 | D3 | DF2 | Automatically | The plates developed cleanly. A very small |
| | | | 15 ml/m² | amount of foam was seen in the developing |
| | | | | section. |
| Example 7 | D3 | DF3 | Automatically | The plates developed cleanly. A very small |
| | | | 15 ml/m² | amount of foam was seen in the developing |
| | | | | section. |
| Comparative Example 8 | D3 | None | 0 | The plates developed cleanly, but high foam |
| | | | | formation was seen in the post rinse section, |
| | | | | resulting in foam exiting the machine. |

The Invention Examples and Comparative Examples show that the metering of defoamers to processing sections of lithographic plate processors allows the use of processing chemicals (developers) that tend to create foam in developing section or in the post rinse section. The low stability of the defoamers under alkaline conditions does not permanently prevent foam formation if the defoamer is added only when the processor is first filled because defoaming efficiency is reduced after a couple of days in most cases.

The invention has been described in detail with particular reference to certain preferred embodiments thereof, but it will be understood that variations and modifications can be effected within the spirit and scope of the invention.

1. A method of forming an image in a lithographic printing plate comprising:
A) imagewise exposing an imageable element comprising a support having thereon at least one imageable layers and optionally, a water-soluble topcoat,
B) optionally pre-rinsing said imagewise exposed element with a pre-rinsing solution to remove said water-soluble topcoat, if present,
C) developing said imagewise exposed element with a developer, and
D) rinsing said developed element with a post-rinsing solution to provide an imaged lithographic printing plate,
wherein a defoamer solution is introduced into at least one of said pre-rinsing solution, developer, and post-rinsing solution as needed in relation to the surface area of processed imageable element.

2. The method of claim 1 wherein said developer contains a surfactant.

3. The method of claim 1 wherein said imageable element comprises a water-soluble topcoat that comprises a surfactant.

4. The method of claim 1 further comprising either or both of the following additional steps:
E) gumming said developed and rinsed element, and
F) drying said gummed element.

5. The method of claim 1 wherein said defoamer solution is introduced into said post-rinsing solution.

6. The method of claim 1 wherein said defoamer solution is metered into at least one of said pre-rinsing solution, developer, and post-rinsing solution at a rate of from about 1 to about 500 ml/m² of processed imageable element.

7. The method of claim 1 wherein said defoamer solution is introduced into at least one of said pre-rinsing solution, developer, and post-rinsing solution additionally in relation to the rate of addition of pre-rinsing, developer, or post-rinsing solution.

8. The method of claim 1 wherein said defoamer solution is formed by diluting a concentrated defoamer solution or dissolving a solid defoamer prior to or simultaneously with metering said defoamer solution into least one of said pre-rinsing solution, developer, and post-rinsing solution.

9. The method of claim 1 wherein said pre-rinsing solution, developer, and post-rinsing solution are provided in separate sections of the same processing apparatus, and at least one of those separate sections comprises a means for introducing said defoamer solution thereto.

10. The method of claim 9 wherein said introducing means is a pump designed to meter said defoamer solution in response to a controller means.

11. The method of claim 1 wherein said defoamer solution comprises a fat defoamer, alkylene oxide adduct, metal soap, silicone or silicone-containing compound, wax defoaming agent, dispersion defoaming agent, or sulfo-carboxylic ester defoaming agent.

12. A method of forming an image in a lithographic printing plate in a processing apparatus comprising multiple processing sections, said method comprising:
A) providing an imagewise exposed imageable element comprising a support having thereon at least one imageable layer and optionally, a water-soluble topcoat,
B) introducing said imagewise exposed imageable element into a pre-rinsing section of said processing apparatus containing a pre-rinsing solution to remove said water-soluble topcoat, if present,
C) introducing said imagewise exposed imageable element into a developer section of said processing apparatus containing a developer,
D) introducing said imagewise exposed and developed imageable element into a rinsing section of said processing apparatus containing a post-rinsing solution,
E) optionally gumming said developed and rinsed element, and
F) optionally drying said gummed element to provide an imaged lithographic printing plate,
wherein a defoamer solution is introduced into at least one of said pre-rinsing, developer, and post-rinsing sections of said processing apparatus at a rate of from about 10 to about 100 ml/m² of processed imageable element.

13. The method of claim 12 wherein said processing apparatus further comprises a preheat section.

14. The method of claim 12 wherein one or more of said pre-rinsing, developer, and post-rinsing sections comprises a spraying means.

15. The method of claim 12 wherein said developer or post-rinsing section comprises means for brushing said imaged element.

16. The method of claim 12 wherein said defoamer solution is introduced into said post-rinsing section of said processing apparatus.
